(19) United States
(12) Patent Application Publication
(10) Pub. No.: US 2026/0144034 A1
(43) Pub. Date: May 21, 2026

(54) SEMICONDUCTOR STRUCTURE HAVING TAPERED VIA AND MANUFACTURING METHOD THEREOF

(71) Applicant: NANYA TECHNOLOGY CORPORATION, NEW TAIPEI CITY (TW)

(72) Inventor: YI-JEN LO, NEW TAIPEI CITY (TW)

(21) Appl. No.: 18/981,761

(22) Filed: Dec. 16, 2024

Related U.S. Application Data
(63) Continuation of application No. 18/951,912, filed on Nov. 19, 2024.

(51) Int. Cl. H01L 23/48; H01L 21/768; H01L 23/00; H01L 25/065; H01L 25/18; H10B 80/00

(52) U.S. Cl. CPC H10W 20/20; H10W 20/023; H10W 90/00; H10B 80/00; H10W 72/01; H10W 72/921; H10W 72/923; H10W 72/931; H10W 72/932; H10W 72/934; H10W 80/312; H10W 80/327; H10W 90/297; H10W 90/724; H10W 90/792

(57) ABSTRACT

The present application provides a semiconductor structure including a first die, a second die and a first via. The first die includes a first substrate, a first interconnect structure having a first conductive pad, and a first bonding layer over the first conductive pad. The second die includes a second bonding layer bonded to the first bonding layer, a second substrate over the second bonding layer, and a second interconnect structure. The first via extends through the second die and the first bonding layer and coupled to the first conductive pad. The first via includes a first portion having a first width and a second portion coupled to the first portion and having a second width different from the first width, wherein the first portion is surrounded by the first bonding layer and adjacent to the second interconnect structure, and the second portion is surrounded by the second substrate.

### CROSS-REFERENCE TO RELATED APPLICATION

This application is a continuation application of U.S. Non-Provisional application No. Ser. No. 18/951,912 filed Nov. 19, 2024, which is incorporated herein by reference in its entirety.

### TECHNICAL FIELD

The present disclosure relates to a semiconductor structure, and a method of manufacturing the semiconductor structure. Particularly, the present disclosure relates to a semiconductor structure having a through-silicon via, and a method of manufacturing the semiconductor structure including forming the through-silicon via.

### DISCUSSION OF THE BACKGROUND

Semiconductor devices are used in a variety of electronic applications, such as personal computers, cellular telephones, digital cameras, and other electronic equipment. Fabrication of semiconductor devices involves sequentially depositing various material layers over a semiconductor wafer, and patterning the material layers using lithography and etching processes to form microelectronic components, including transistors, diodes, resistors and/or capacitors, on or in the semiconductor wafer.

The semiconductor industry continues to improve integration density of the microelectronic components by continual reduction of minimum feature size, which allows more components to be integrated into a given area. Smaller package structures with smaller footprints are developed to package the semiconductor devices, in order to facilitate formation and integration of components of different sizes. However, such formation and integration may increase complexity of manufacturing processes. It is therefore desirable to develop improvements that address the aforementioned challenges.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes a first die, a second die and a first via. The first die includes a first substrate, a first dielectric layer over the first substrate, a first interconnect structure disposed within the first dielectric layer and having a first conductive pad, and a first bonding layer over the first dielectric layer, wherein the first conductive pad is at least partially exposed through the first dielectric layer. The second die includes a second bonding layer bonded to the first bonding layer, a second substrate over the second bonding layer, and a second interconnect structure between the second bonding layer and the second substrate. The first via extends through the second die and the first bonding layer and coupled to the first conductive pad.

The first via includes a first portion having a first width and a second portion coupled to the first portion and having a second width different from the first width, wherein the first portion is surrounded by the first bonding layer and adjacent to the second interconnect structure, and the second portion is surrounded by the second substrate.

Another aspect of the present disclosure provides a semiconductor structure. The semiconductor structure includes a first die, a second die, a third die, a first via and a second via. The first die includes a first substrate, a first interconnect structure disposed over the first substrate and having a first conductive pad, and a first bonding layer over the first conductive pad. The second die includes a second bonding layer bonded to the first bonding layer, a second substrate over the second bonding layer, and a second interconnect structure between the second bonding layer and the second substrate. The third die includes a third bonding layer bonded to the second die, a third substrate over the third bonding layer, and a third interconnect structure between the third bonding layer and the third substrate. The first via extends through the second die and into the first die. The second via extends through the third die and electrically connected to the first via. The second die is disposed between the first die and the third die, the first via possesses a tapered cross-sectional profile, a first contact surface area of the first via is in contact with a second contact surface area of the second via, and a dimension of the first contact surface area is different from a dimension of the second contact surface area.

Another aspect of the present disclosure provides a method of manufacturing a semiconductor structure. The method includes steps of forming a first die, forming a second die, and bonding the second die over the first die. The formation of the first die includes providing a first substrate and a first dielectric layer over the first substrate, forming a first interconnect structure within the first dielectric layer and having a first conductive pad, disposing a first bonding layer over the first dielectric layer and in contact with the first conductive pad.

The formation of the second die includes providing a second substrate and a second dielectric layer over the second substrate, forming a second interconnect structure within the second dielectric layer and having a second conductive pad, disposing a second bonding layer over the second dielectric layer and in contact with the second conductive pad.

The method further includes bonding the first bonding layer to the second bonding layer to bond the first die to the second die; removing a portion of the second die and a portion of the first bonding layer to form a first opening, wherein the first conductive pad is exposed through the first opening, and the first opening includes a first part having a first width surrounded by the first die and a second part having a second width different from the first width; and disposing a first conductive material into the first opening to form a first via. The first via includes a first portion having the first width and a second portion coupled to the first portion and having the second width.

In conclusion, a first die is bonded to a second die by fusion bonding, and a through silicon via (TSV) in the second die and extended into the first die and electrically coupled to a conductive pad of the first dia. A dielectric-to-dielectric bonding interface is formed between the first die and the second die, the TSV possesses a tapered cross-sectional profile, and no de-bonding layer (temporary layer) between the first die and the second die is needed. A plurality of processes (such as de-bonding process, flipped upside down process and micro-bump bonding process) can be omitted, and a thickness of the semiconductor structure may be decreased to increase density of the semiconductor structure (z-height of the product). As a result, the costs are reduced, and favorable electrical performance and reliability of the high-density semiconductor structure are guaranteed.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures'reference numbers, which refer to similar elements throughout the description.

FIG. 1 is a cross-sectional view of a first semiconductor structure in accordance with some embodiments of the present disclosure.

FIG. 2 is an embodiment of a top cross-sectional view of various embodiments of a first via and a second via of the first semiconductor structure along a line A-A′ in FIG. 1.

FIG. 3 is an embodiment of a top cross-sectional view of various embodiments of a first via and a second via of the first semiconductor structure along a line A-A′ in FIG. 1.

FIG. 4 is an embodiment of a top cross-sectional view of various embodiments of a first via and a second via of the first semiconductor structure along a line A-A′ in FIG. 1.

FIG. 5 is a cross-sectional view of a second semiconductor structure in accordance with some embodiments of the present disclosure.

FIG. 6 is a flow diagram illustrating a method of manufacturing a semiconductor structure in accordance with some embodiments of the present disclosure.

FIGS. 7A, 7B, 8A, 8B, 9 through 12, 13A, 13B and 14 through 23 illustrate cross-sectional views of intermediate stages in the formation of a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

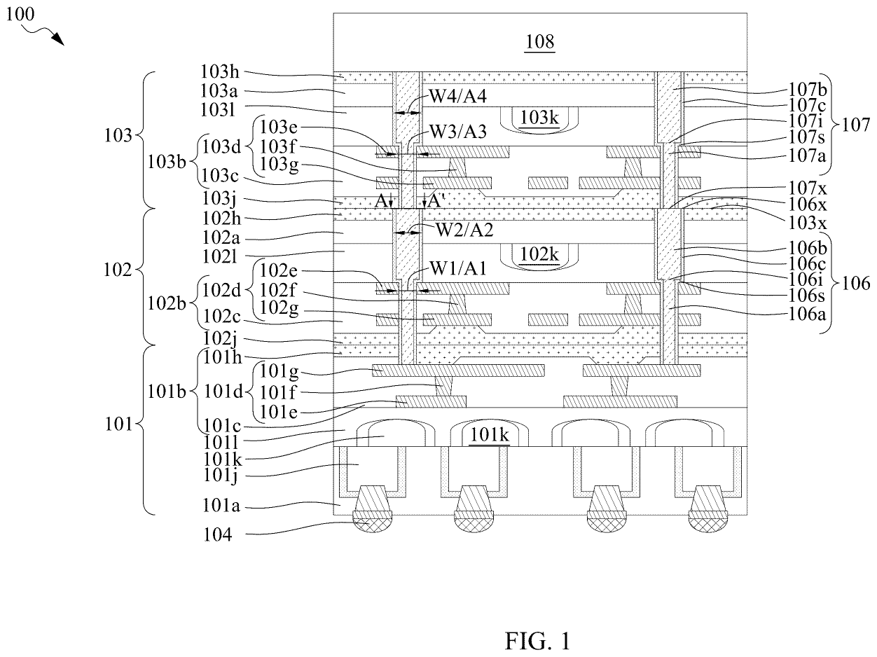

FIG. 1 is a schematic cross-sectional view of a first semiconductor structure 100 in accordance with some embodiments of the present disclosure. In some embodiments, the first semiconductor structure 100 is a part of a die, a package or a device. In some embodiments, the first semiconductor structure 100 is a die, a package or a device. In some embodiments, the first semiconductor structure 100 is a bonded structure.

In some embodiments, the first semiconductor structure 100 includes a first die 101 and a second die 102 stacked over the first die 101. In some embodiments, the first die 101 and the second die 102 comprise any of various known types of semiconductor devices such as accelerated processing unit (APU), memories, dynamic random-access memory (DRAM), NAND flash memory, central processing unit (CPU), graphic processing unit (GPU), microprocessors, application-specific integrated circuits (ASICs), digital signal processors (DSPs), logic die, or the like. In some embodiments, the first die 101 is a logic die.

In some embodiments, the first die 101 includes a first substrate 101a, a first passivation layer 101l over the substrate 101a, at least one first electrical device 101k disposed within the first passivation layer 101l, a first interconnect layer 101b over the first passivation layer 101l and the first electrical device 101k, and a first bonding layer 101h over the first interconnect layer 101b. In some embodiments, the first substrate 101a is a semiconductive layer. In some embodiments, the first substrate 101a includes semiconductive material such as silicon, germanium, gallium, arsenic, or a combination thereof. In some embodiments, the first substrate 101a is a silicon substrate.

In some embodiments, the first electrical devices 101k comprise any of various known types of semiconductor devices such as N-type metal-oxide semiconductor (NMOS) and/or P-type metal-oxide semiconductor (PMOS) devices, capacitors, resistors, diodes, photodiodes, fuses, and/or the like. In some embodiments, the first electrical devices 101k are electrically connected to an external circuitry (not shown) and the first interconnect layer 101b. In some embodiments, the first electrical devices 101k are surrounded by the first passivation layer 101l. In some embodiments, the first passivation layer 101l is disposed between the first substrate 101a and the first interconnect layer 101b. In some embodiments, the first passivation layer 101l includes dielectric material such as oxide, nitride, silicon dioxide, silicon nitride, silicon oxynitride, silicon carbide, polymer or the like.

In some embodiments, the first interconnect layer 101b is disposed over a front side of the first substrate 101a. In some embodiments, the first interconnect layer 101b is disposed over the first passivation layer 101l. In some embodiments, the first interconnect layer 101b includes a first dielectric layer 101c and a first interconnect structure 101d surrounded by the first dielectric layer 101c. In some embodiments, the first dielectric layer 101c is disposed above the first substrate 101a. In some embodiments, the first dielectric layer 101c includes dielectric material such as oxide, nitride, silicon dioxide, silicon nitride, silicon oxynitride, silicon carbide, polymer or the like. In some embodiments, the first dielectric layer 101c includes several dielectric layers stacked over each other. In some embodiments, each of the dielectric layers includes materials that are same as or different from materials in others of the dielectric layers.

In some embodiments, the first interconnect structure 101d includes a first pad portion 101e, a first via portion 101f and a first conductive pad 101g. In some embodiments, the first pad portion 101e and the first via portion 101f are embedded in the first dielectric layer 101c. In some embodiments, the first pad portion 101e extends laterally within the first dielectric layer 101c, and the first via portion 101f extends vertically within the first dielectric layer 101c. In some embodiments, the first via portion 101f is electrically coupled to the first pad portion 101e. In some embodiments, the first pad portion 101e and the first via portion 101f include conductive material such as gold, silver, copper, nickel, tungsten, aluminum, tin, alloys thereof, or the like.

In some embodiments, the first conductive pad 101g is disposed above the first pad portion 101e and the first via portion 101f. In some embodiments, the first conductive pad 101g is surrounded by the first dielectric layer 101c and is at least partially exposed through the first dielectric layer 101c. In some embodiments, the first conductive pad 101g is electrically connected to the first pad portion 101e through the first via portion 101f. In some embodiments, the first conductive pad 101g is in contact with the first via portion 101f. In some embodiments, the first conductive pad 101g includes conductive material such as gold, silver, copper, nickel, tungsten, aluminum, tin, alloys thereof, or the like. In some embodiments, a top surface or a bottom surface of the first conductive pad 101g has a circular, quadrilateral or polygonal shape.

In some embodiments, the first bonding layer 101h is disposed over the first interconnect layer 101b and the first substrate 101a. In some embodiments, the first bonding layer 101h includes dielectric material such as oxide, nitride, silicon dioxide, silicon nitride, silicon oxynitride, silicon carbide, polymer or the like. In some embodiments, the first bonding layer 101h is configured to form a bond with another bonding layer. In some embodiments, a top surface of the first conductive pad 101g is exposed and is in contact with the first bonding layer 101h. In some embodiments, the first conductive pad 101g is partially covered by the first bonding layer 101h.

In some embodiments, the second die 102 is disposed above the first die 101. In some embodiments, the first die 101 and the second die 102 are face to face. In some embodiments, the second die 102 is flipped upside down and includes a second substrate 102a, a second passivation layer 102l under the second substrate 102a, a second electrical device 102k within the second passivation layer 102l, a second interconnect layer 102b under the second passivation layer 102l, a second bonding layer 102j under the second interconnect layer 102b, and a fourth bonding layer 102h over the second substrate 102a. In some embodiments, the second substrate 102a is a semiconductive layer. In some embodiments, the second substrate 102a includes semiconductive material. In some embodiments, the second substrate 102a is a silicon substrate.

In some embodiments, the second bonding layer 102j is bonded to the first bonding layer 101h. In some embodiments, the second bonding layer 102j includes dielectric material such as oxide, nitride, silicon dioxide, silicon nitride, silicon oxynitride, silicon carbide, polymer or the like. In some embodiments, the second die 102 is bonded to the first die 101 by bonding the first bonding layer 101h to the second bonding layer 102j. In some embodiments, a top surface or a bottom surface of the second conductive pad 102g is exposed and is in contact with the second bonding layer 102j. In some embodiments, the second conductive pad 102g is partially covered by the second bonding layer 102j.

In some embodiments, the second interconnect layer 102b includes a second dielectric layer 102c and a second interconnect structure 102d surrounded by the second dielectric layer 102c. In some embodiments, the second dielectric layer 102c is disposed between the second substrate 102a and the second bonding layer 102j. In some embodiments, the second dielectric layer 102c includes dielectric material such as oxide, nitride, silicon dioxide, silicon nitride, silicon oxynitride, silicon carbide, polymer or the like. In some embodiments, the second dielectric layer 102c includes several dielectric layers stacked over each other. In some embodiments, each of the dielectric layers includes materials that are same as or different from materials in others of the dielectric layers.

In some embodiments, the second interconnect structure 102d includes a second pad portion 102e, a second via portion 102f and a second conductive pad 102g. In some embodiments, the second pad portion 102e and the second via portion 102f are embedded in the second dielectric layer 102c. In some embodiments, the second pad portion 102e extends laterally within the second dielectric layer 102c, and the second via portion 102f extends vertically within the second dielectric layer 102c. In some embodiments, the second via portion 102f is electrically coupled to the second pad portion 102e. In some embodiments, the second pad portion 102e is at least partially exposed through the second dielectric layer 102c. In some embodiments, the second pad portion 102e and the second via portion 102f include conductive material such as gold, silver, copper, nickel, tungsten, aluminum, tin, alloys thereof, or the like.

In some embodiments, the second conductive pad 102g is disposed under the second pad portion 102e and the second via portion 102f. In some embodiments, the second conductive pad is surrounded by the second dielectric layer 102c and is at least partially exposed through the second dielectric layer 102c. In some embodiments, the second conductive pad is electrically connected to the second pad portion 102e through the second via portion 102f. In some embodiments, the second conductive pad 102g is in contact with the second via portion 102f. In some embodiments, the second conductive pad 102g include conductive material such as gold, silver, copper, nickel, tungsten, aluminum, tin, alloys thereof, or the like. In some embodiments, a bottom surface or a bottom surface of the second conductive pad 102g has a circular, quadrilateral or polygonal shape.

In some embodiments, the second electrical devices 102k comprise any of various known types of semiconductor devices such as NMOS and/or PMOS devices, capacitors, resistors, diodes, photodiodes, fuses, and/or the like. In some embodiments, the second electrical device 102k is electrically connected to an external circuitry and the second interconnect layer 102b. In some embodiments, the second electrical devices 102k are surrounded by the second passivation layer 102l. In some embodiments, the second passivation layer 102l is disposed between the second substrate 101a and the second interconnect layer 102b. In some embodiments, the second passivation layer 102l includes dielectric material such as oxide, nitride, silicon dioxide, silicon nitride, silicon oxynitride, silicon carbide, polymer or the like.

In some embodiments, the fourth bonding layer 102h is disposed over the second substrate 102a. In some embodiments, the fourth bonding layer 102h includes dielectric material such as oxide, nitride, silicon dioxide, silicon nitride, silicon oxynitride, silicon carbide, polymer or the like. In some embodiments, the fourth bonding layer 102h is configured to form a bond with another bonding layer. In some embodiments, the second substrate 102a is covered by the fourth bonding layer 102h.

A first via 106 extends through the second die 102 and into the first die 101. In some embodiments, the semiconductor structure 100 includes a plurality of first vias 106. In some embodiments, the first via 106 extends through the second die 102, the first bonding layer 101h, the second bonding layer 102j and coupled to the first conductive pad. In some embodiments, the first via 106 is a through substrate via (TSV). A dielectric-to-dielectric bonding interface and the first via 106 are formed between the first die 101 and the second die 102, and micro-bumps are no need between the first die 101 and the second die 102. As a result, the first via 106 in the second die 102 and extended into the first die 101 can improve an overall structure and reliability of the first semiconductor structure 100.

In some embodiments, the second die 102 and at least a portion of the first die 101 surround the first via 106. In some embodiments, the second die 102 and the first bonding layer 101h surround the first via 106. In some embodiments, the first via 106 is electrically isolated from the second interconnect structure 102d.

In some embodiments, the first via 106 protrudes from the first conductive pad 101g to the second die 102. In some embodiments, the first via 106 includes conductive material such as gold, silver, copper, nickel, tungsten, aluminum, tin, alloys thereof, or the like. In some embodiments, the first via 106 extends in a direction orthogonal to the first conductive pad 101g.

In some embodiments, the first via 106 possesses a tapered cross-sectional profile. Due to the cross-sectional profile of the first via 106, the reliability of the first semiconductor structure 100 including the first die 101 and the second die 102 bonded with each other is improved. In some embodiments, the first via 106 includes a first portion 106a having a first width W1 and a second portion 106b coupled to the first portion 106a and having a second width W2 different from the first width W1. In some embodiments, since the first width W1 is different from the second width W2, the first via 106 has a step-shaped structure 106s disposed at an interface 106i of the first portion 106a and the second portion 106b. In some embodiments, the first portion 106a and the second portion 106b are integral.

In some embodiments, the first portion 106a of the first via 106 is disposed between the second portion 106b of the first via 106 and the first conductive pad 101g. In some embodiments, the first portion 106a is surrounded by the first bonding layer 101h and the second interconnect layer 102b, and the second portion 106b is surrounded by the second passivation layer 102l, the second substrate 102a and the fourth bonding layer 102h.

In some embodiments, the second width W2 is greater than the first width W1. In some embodiments, the second width W2 is less than the first width W1. In some embodiments, the first portion 106a has a first cross-sectional area A1 and the second portion 106b has a second cross-sectional area A2, and a dimension of first cross-sectional area A1 is different from a dimension of the second cross-sectional area A2. In some embodiments, the dimension of the second cross-sectional area A2 is greater than the dimension of the first cross-sectional area A1. In some embodiments, the dimension of the second cross-sectional area A2 is less than the dimension of the first cross-sectional area A1. The first cross-sectional area A1 and the second cross-sectional area A2 have similar or different shapes. In some embodiments, each of the first cross-sectional area A1 and the second cross-sectional area A2 can be a circular, quadrilateral or polygonal shape.

In some embodiments, the first via 106 further includes a barrier layer 106c surrounding the first portion 106a and the second portion 106b. In some embodiments, the barrier layer 106c is disposed between the second die 102 and the first portion 106a and between the second die 102 and the second portion 106b. In some embodiments, the barrier layer 106c is a diffusion barrier such as a titanium nitride layer, a tantalum nitride layer, a titanium layer, a tantalum layer, or the like.

In some embodiments, the first semiconductor structure 100 further includes a third die 103 stacked over the second die 102 and the first die 101. In some embodiments, the third die 103 has a configuration similar to that of the second die 102.

In some embodiments, the third die 103 is disposed above the second die 102. In some embodiments, the third die 103 and the second die 102 are face to back. In some embodiments, the third die 103 is flipped upside down and includes a third substrate 103a, a third passivation layer 103l under the third substrate 103a, a third electrical device 103k within the third passivation layer 103l, a third interconnect layer 103b under the third passivation layer 103l, a third bonding layer 103j under the third interconnect layer 103b, and a fifth bonding layer 103h over the third substrate 103a. In some embodiments, the third substrate 103a is a semiconductive layer. In some embodiments, the third substrate 103a is a silicon substrate.

In some embodiments, the third bonding layer 103j is bonded to the second bonding layer 102h. In some embodiments, the third bonding layer 103j includes dielectric material. In some embodiments, the third die 103 is bonded to the second die 102 by bonding the third bonding layer 103j to the fourth bonding layer 102h. In some embodiments, a top surface or a bottom surface of the third conductive pad 103g is exposed and is in contact with the third bonding layer 103j. In some embodiments, the third conductive pad 103g is partially covered by the third bonding layer 103j.

In some embodiments, the third interconnect layer 103b includes a third dielectric layer 103c and a third interconnect structure 103d surrounded by the third dielectric layer 103c. In some embodiments, the third dielectric layer 103c is disposed between the third substrate 103a and the third bonding layer 103j. In some embodiments, the third dielectric layer 103c includes dielectric material.

In some embodiments, the third interconnect structure 103d includes a third pad portion 103e, a third via portion 103f and a third conductive pad 103g. In some embodiments, the third pad portion 102e and the second via portion 103f are embedded in the third dielectric layer 103c. In some embodiments, the third pad portion 103e extends laterally within the third dielectric layer 103c, and the third via portion 103f extends vertically within the third dielectric layer 103c. In some embodiments, the third via portion 103f is electrically coupled to the third pad portion 103e. In some embodiments, the third pad portion 103e is at least partially exposed through the third dielectric layer 103c. In some embodiments, the third pad portion 103e and the third via portion 103f include conductive material.

In some embodiments, the third conductive pad 103g is disposed under the third pad portion 103e and the third via portion 103f. In some embodiments, the third conductive pad 103g is surrounded by the third dielectric layer 103c and is at least partially exposed through the third dielectric layer 103c. In some embodiments, the third conductive pad 103g is electrically connected to the third pad portion 103e through the third via portion 103f. In some embodiments, the third conductive pad 103g is in contact with the third via portion 103f. In some embodiments, the third conductive pad 103g include conductive material. In some embodiments, a bottom surface or a top surface of the third conductive pad 103g has a circular, quadrilateral or polygonal shape.

In some embodiments, the third electrical devices 103k comprise any of various known types of semiconductor devices such as NMOS and/or PMOS devices, capacitors, resistors, diodes, photodiodes, fuses, and/or the like. In some embodiments, the third electrical device 103k is electrically connected to an external circuitry and the third interconnect layer 103b. In some embodiments, the third electrical devices 103k are surrounded by the third passivation layer 103l. In some embodiments, the third passivation layer 103l is disposed between the third substrate 103a and the third interconnect layer 103b. In some embodiments, the third passivation layer 103l includes dielectric material.

In some embodiments, the fifth bonding layer 103h is disposed over the third substrate 103a. In some embodiments, the fifth bonding layer 103h includes dielectric material. In some embodiments, the fifth bonding layer 103h is configured to form a bond with another component, such as a carrier substrate 108. In some embodiments, the third substrate 103a is covered by the fourth bonding layer 103h.

A second via 107 extends through the third die 103, the third bonding layer 103j and the fourth bonding layer 102h, and electrically connected the first via 106. In some embodiments, the second via 107 extends through the third die 103 and coupled to the second portion 106b of the first via 106. In some embodiments, the second via 107 is a TSV. A dielectric-to-dielectric bonding interface and a second contact surface area 107x of the second via 107 are formed between the second die 102 and the third die 103, micro-bumps are no need between the second die 102 and the third die 103. As a result, the second via 107 in the third die 103 can improve an overall structure and reliability of the first semiconductor structure 100.

In some embodiments, the third die 103 surrounds the second via 107. In some embodiments, the second via 107 is electrically isolated from the third interconnect structure 103d. In some embodiments, the first via 106 and the second via 107 are vertically stacked and form a vertical interconnection of the semiconductor device 100. In some embodiments, the first via 106 is disposed between the second via 107 and the first conductive pad 101g, and the first via 106 and the second via 107 improve the overall structure and reliability of the first semiconductor structure 100. In some embodiments, the semiconductor structure 100 includes a plurality of second vias 102. In some embodiments, each of the plurality of second vias 102 couples to the corresponding one of the plurality of the first vias 106. In some embodiments, a number of the plurality of the first vias 106 is identical to a number of the plurality of second vias 102.

In some embodiments, the second via 107 includes conductive material such as gold, silver, copper, nickel, tungsten, aluminum, tin, alloys thereof, or the like. In some embodiments, the first via 106 and the second via 107 include a same material. In some embodiments, the first via 106 and the second via 107 extends in same direction. In some embodiments, the second via 107 extends in a direction orthogonal to the third conductive pad 103g.

In some embodiments, the second via 107 possesses a tapered cross-sectional profile. Due to the cross-sectional profile of the second via 107, the reliability of the first semiconductor structure 100 including the second die 102 and the third die 103 bonded with each other is improved. In some embodiments, the second via 107 includes a third portion 107a having a third width W3 and a fourth portion 107b coupled to the third portion 107a and having a fourth width W4. In some embodiments, the third width W3 is different from the fourth width W4, and the second via 107 has a step-shaped structure 106s disposed at an interface 107i of the third portion 107a and the fourth portion 107b. In some embodiments, the third portion 107a and the fourth portion 107b are integral.

In some embodiments, the third portion 107a of the second via 107 is disposed between the fourth portion 107b of the second via 107 and the first via 106. In some embodiments, the third portion 107a is surrounded by the third interconnect layer 103b, and the fourth portion 107b is surrounded by the third passivation layer 103l, the third substrate 103a and the fifth bonding layer 103h.

In some embodiments, the fourth width W4 is greater than the third width W3. In some embodiments, the fourth width W4 is less than the third width W3. In some embodiments, the third portion 107a has a third cross-sectional area A3 and the fourth 107b portion has a fourth cross-sectional area A4, and a dimension of third cross-sectional area A3 is different from a dimension of the fourth cross-sectional area A4. In some embodiments, the dimension of the fourth cross-sectional area A4 is greater than the dimension of the third cross-sectional area A3. In some embodiments, the dimension of the fourth cross-sectional area A4 is less than the dimension of the third cross-sectional area A3. The third cross-sectional area A3 and the fourth cross-sectional area A4 have a similar shape or different shapes. In some embodiments, each of the third cross-sectional area A3 and the fourth cross-sectional area A4 can be a circular, quadrilateral or polygonal shape.

In some embodiments, the second via 107 further includes a barrier layer 107c surrounding the third portion 107a and the fourth portion 107b. In some embodiments, the barrier layer 107c is disposed between the third die 103 and the third portion 107a and between the third die 103 and the fourth portion 107b. In some embodiments, the barrier layer 107c includes a diffusion barrier such as a titanium nitride layer, a tantalum nitride layer, a titanium layer, a tantalum layer, or the like.

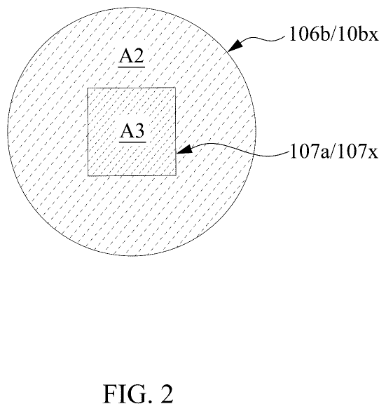

FIGS. 2 to 4 show the first via 106 and the second via 107 in various shapes. Referring to FIGS. 1 to 4, a first contact surface area 106x of the first via 106 is in contact with the second contact surface area 107x of the second via 107, and a dimension of the first contact surface area 106x is different from a dimension of the second contact surface area 107x. In some embodiments, each of the first contact surface area 106x and the second contact surface area 107x has a circular, quadrilateral or polygonal shape. In some embodiments, the second width W2 is greater than the third width W3. In some embodiments, the dimension of the first contact surface area 106x is substantially greater than the dimension of the second contact surface area 107x, the first contact surface area 106x is in contact with the second contact surface area 107x and the third bonding layer 103j. In some embodiments, the second width W2 is less than the third width W3. In some embodiments, the dimension of the second contact surface area 107x is substantially greater than the dimension of the first contact surface area 106x, the second contact surface area 107x is in contact with the first contact surface area 106x and the fourth bonding layer 102h. In some embodiments, the first contact surface area 106x and the second contact surface area 107x form a step-shaped structure. In some embodiments, an interface 103x of the second die 102 and the third die 103 is coplanar with the first contact surface area 106x and the second contact surface area 107x.

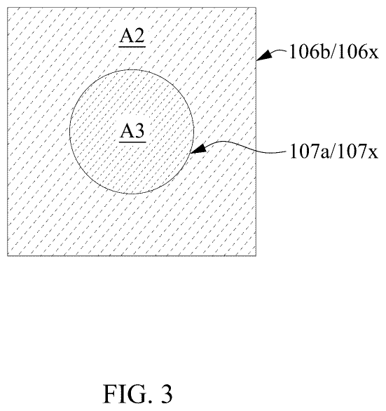

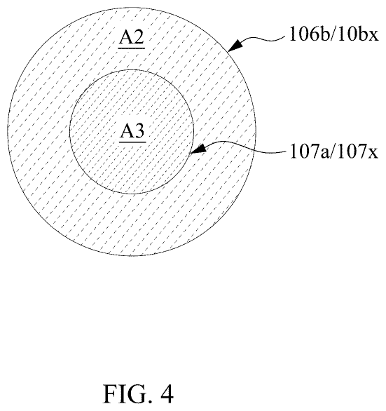

As shown in FIGS. 2 and 3, a cross section of the third portion 107a of the second via 107 and a cross section the second portion 106b of the first via 106 have different shapes. In some embodiments, the first contact surface area 106x is in a shape of circular, and the second contact surface area 107x is in a shape of quadrilateral as shown in FIG. 2. In some embodiments, the first contact surface area 106x is in a shape of quadrilateral, and the second contact surface area 107x is in a shape of circular as shown in FIG. 3. As shown in FIG. 4, the cross section of the third portion 107a of the second via 107 and the cross section the second portion 106b of the first via 106 have a same shape.

In some embodiments, referring back to FIG. 1, a conductive bump 104 is disposed under the first die 100. In some embodiments, the conductive bump 104 is received by the first substrate 101a and electrically connected to a third via 101j disposed within the first substrate 101a. In some embodiments, the conductive bump 104 is configured to connect to an external circuitry or an external interconnect structure. In some embodiments, the conductive bump 104 is electrically connected to the first die 101, the second die 102 and the third die 103 through the third via 101j.

In some embodiments, the conductive bump 104 includes low-temperature reflowable material. In some embodiments, the conductive bump 104 includes soldering material such as tin, lead, silver, copper, nickel, bismuth, or a combination thereof. In some embodiments, the conductive bump 104 includes conductive material such as gold, silver, copper, nickel, tungsten, aluminum, tin, alloys thereof, or the like. In some embodiments, the conductive bump 104 is a ball grid array (BGA) ball, a controlled collapse chip connection (C4) bump, a microbump or the like.

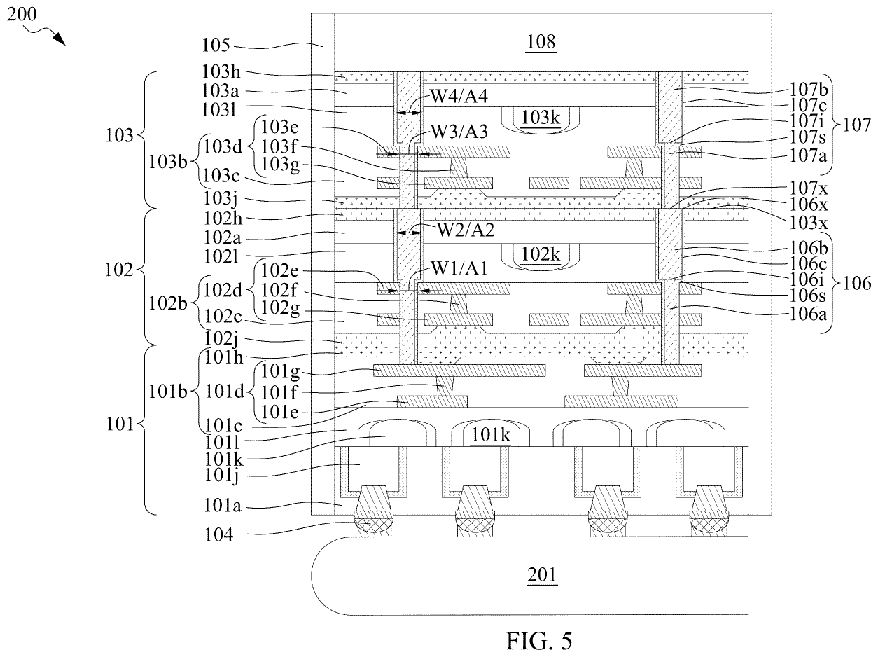

FIG. 5 is a schematic cross-sectional view of a second semiconductor structure 200 in accordance with some embodiments of the present disclosure. The second semiconductor structure 200 includes the first semiconductor structure 100, a molding 105, and an interposer 201. In some embodiments, the molding 105 surrounds the first die 101, the second die 102 and the third die 103. In some embodiments, the first semiconductor structure 100 is electrically connected to the interposer 201 through the conductive bump 104.

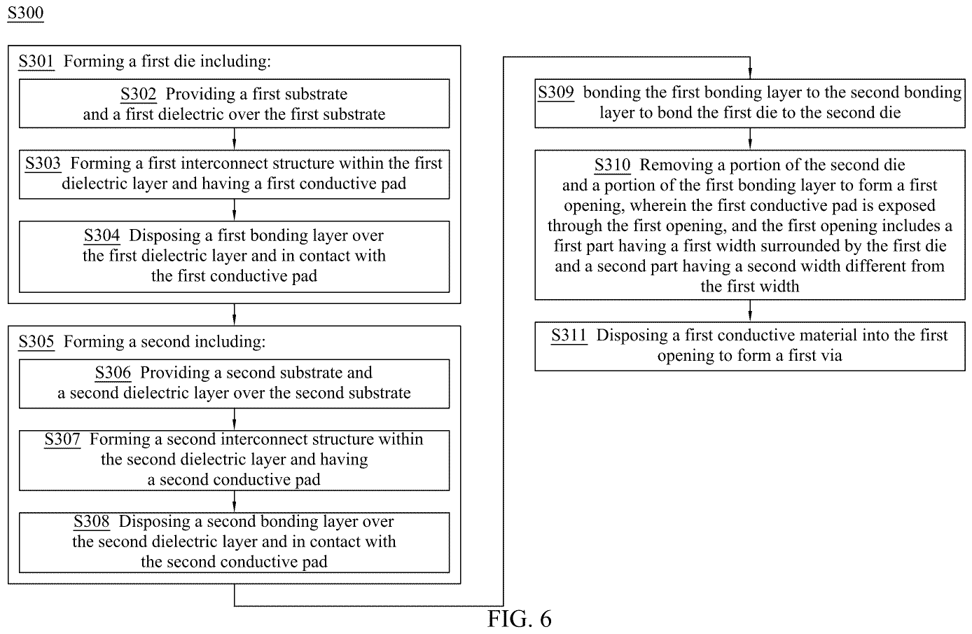

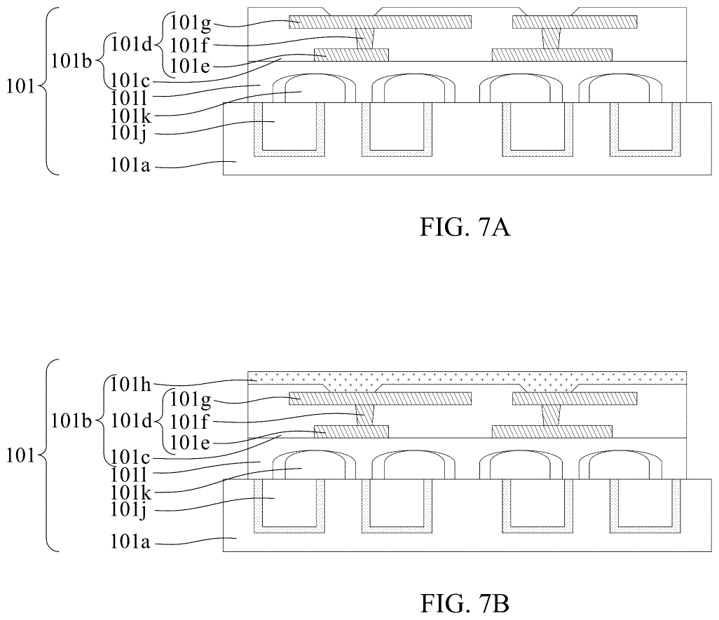

FIG. 6 is a flow diagram illustrating a method S300 of manufacturing the first semiconductor structure 100 in accordance with some embodiments of the present disclosure, and FIGS. 7A, 7B, 8A, 8B, 9 through 12, 13A, 13B and 14 through 23 illustrate cross-sectional views of intermediate stages in the formation of the first semiconductor structure 100 and the second semiconductor structure 200 in accordance with some embodiments of the present disclosure.

The stages shown in FIGS. 7A, 7B, 8A, 8B, 9 through 12, 13A, 13B and 14 through 23 are also illustrated schematically in the flow diagram in FIG. 6. In the following description, the fabrication stages shown in FIGS. 7A, 7B, 8A, 8B, 9 through 12, 13A, 13B and 14 through 23 are discussed in reference to the process steps shown in FIG. 6. The method S300 includes a number of operations and the description and illustration are not deemed as a limitation to the sequence of the operations. The method S300 includes a number of steps (S301, S302, S303, S304, S305, S306, S307, S308, S309, S310 and S311).

Referring to FIGS. 7A to 7B, a first die 101 is formed according to step S301 in FIG. 6. Referring to FIG. 7A, the formation of the first die 101 includes providing a first substrate 101a and a first dielectric layer 101c over the first substrate 101a according to step S302 in FIG. 6. In some embodiments, the first substrate 101a is a semiconductive layer. In some embodiments, the first substrate 101a includes semiconductive material. In some embodiments, the first substrate 101a is a silicon substrate.

In some embodiments, the first dielectric layer 101c is disposed above the first substrate 101a. In some embodiments, the first dielectric layer 101c includes dielectric material. In some embodiments, the first dielectric layer 101c is formed by deposition, chemical vapor deposition (CVD) or another suitable process. In some embodiments, a first passivation layer 101l is formed between the first substrate 101a and the first dielectric layer 101c, and a first electrical device 101k is formed over the first substrate 101a and within the first passivation layer 101l. In some embodiments, a third via 101j is formed in the first substrate 101a and electrically connected to the first electrical device 101k.

In some embodiments, a first interconnect structure 101d is formed within the first dielectric layer 101c. In some embodiments, the first interconnect structure 101d includes a first pad portion 101e and a first via portion 101f. In some embodiments, the first pad portion 101e and the first via portion 101f include conductive material. In some embodiments, the first pad portion 101e and the first via portion 101f are formed by removing several portions of the first dielectric layer 101c to form several recesses and disposing conductive materials to fill the recesses to form the first pad portion 101e and the first via portion 101f. In some embodiments, the conductive material is disposed by electroplating, sputtering or another suitable process.

In some embodiments, a first interconnect structure 101d within the first dielectric layer 101c and having a first conductive pad 101g is formed according to step S303 in FIG. 6. In some embodiments, the first conductive pad 101g is at least partially exposed through the first dielectric layer 101c. In some embodiments, the first conductive pad 101g is formed by removing a portion of the first dielectric layer 101c to form a recess, and then disposing conductive material to fill the recess to form the first conductive pad 101g. In some embodiments, the conductive material is disposed by electroplating, sputtering or another suitable process.

Referring to FIG. 7B, a first bonding layer 101h is disposed over the first dielectric layer 101c and in contact with the first conductive pad 101g according to step S304 in FIG. 6. In some embodiments, the first bonding layer 101h includes dielectric material. In some embodiments, a top surface of the first conductive pad 101g is covered by and in contact with the first bonding layer 101h and the first dielectric layer 101c. In some embodiments, the first bonding layer 101h is disposed by deposition, CVD or another suitable process.

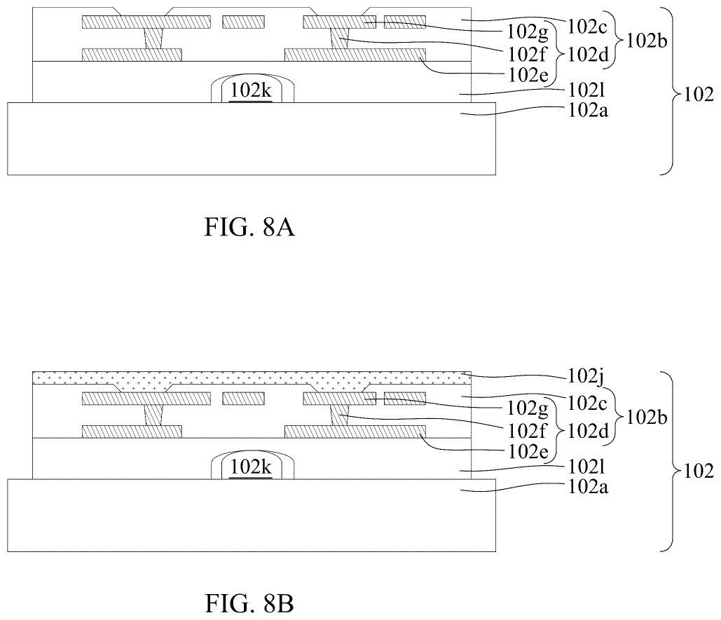

Referring to FIGS. 8A and 8B, a second die 102 is formed according to step S305 in FIG. 6. Referring to FIG. 8A, the formation of the second die 102 includes providing a second substrate 102a and a second dielectric layer 102c over the second substrate 102a according to step S306 in FIG. 6. In some embodiments, the second substrate 102a is a semiconductive layer. In some embodiments, the second substrate 102a includes semiconductive material.

In some embodiments, the second dielectric layer 102c is disposed above the second substrate 102a. In some embodiments, the second dielectric layer 102c includes dielectric material. In some embodiments, the second dielectric layer 102c is formed by deposition, CVD or another suitable process. In some embodiments, a second passivation layer 102l is formed between the second substrate 102a and the second dielectric layer 102c, and a second electrical device 102k is formed over the second substrate 102a and within the second passivation layer 102l.

In some embodiments, a second interconnect structure 102d is formed within the second dielectric layer 102c. In some embodiments, the second interconnect structure 102d includes a second pad portion 102e and a second via portion 102f. In some embodiments, the second pad portion 102e and the second via portion 102f include conductive material. In some embodiments, the second pad portion 102e and the second via portion 102f are formed by removing several portions of the second dielectric layer 102c to form several recesses and disposing conductive materials to fill the recesses to form the second pad portion 102e and the second via portion 102f. In some embodiments, the conductive material is disposed by electroplating, sputtering or another suitable process.

In some embodiments, a second interconnect structure 102d within the second dielectric layer 102c and having a second conductive pad 102g is formed according to step S307 in FIG. 6. In some embodiments, the second conductive pad 102g is at least partially exposed through the second dielectric layer 102c. In some embodiments, the second conductive pad 102g is formed by removing a portion of the second dielectric layer 102c to form a recess, and then disposing conductive material to fill the recess to form the second conductive pad 102g. In some embodiments, the conductive material is disposed by electroplating, sputtering or another suitable process.

Referring to FIG. 8B, a second bonding layer 102j is disposed over the second dielectric layer 102c and in contact with the second conductive pad 102g according to step S308 in FIG. 6. In some embodiments, the second bonding layer 102j includes dielectric material. In some embodiments, a top surface of the second conductive pad 102g is covered by and in contact with the second bonding layer 102j and the second dielectric layer 102c. In some embodiments, the second bonding layer 102j is disposed by deposition, CVD or another suitable process.

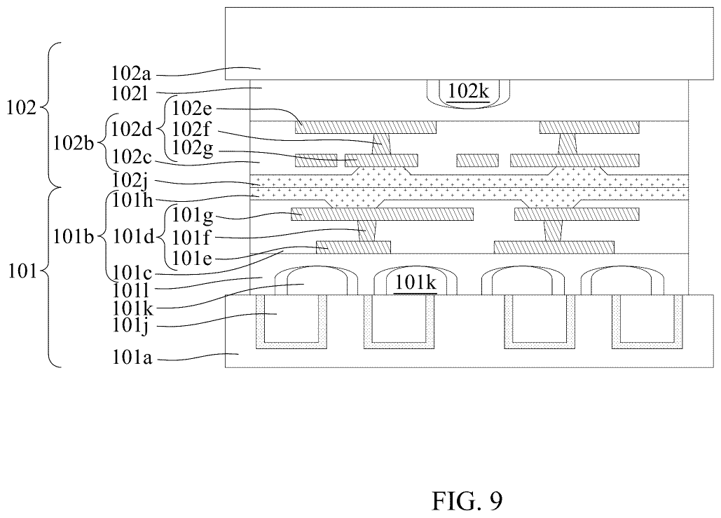

Referring to FIG. 9, the first bonding layer 101h is bonded to the second bonding layer 102j to bond the first die 106 to the second die 107 according to step S309 in FIG. 6. Referring to FIG. 9, the second die 102 is bonded to the first die 101.

In some embodiments, the first die 101 and the second die 102 are respectively formed. In some embodiments, the formation of the first die 101 and the formation of the second die 102 are performed simultaneously or separately. In some embodiments, the second die 102 is flipped after the formation of the second die 102 and prior to the bonding of the second die 102 to the first die 101.

In some embodiments, a fusion bonding is performed to bond the first die 101 to the second die 102. In some embodiments, the fusion bonding includes bonding the first bonding layer 101h to the second bonding layer 102j.

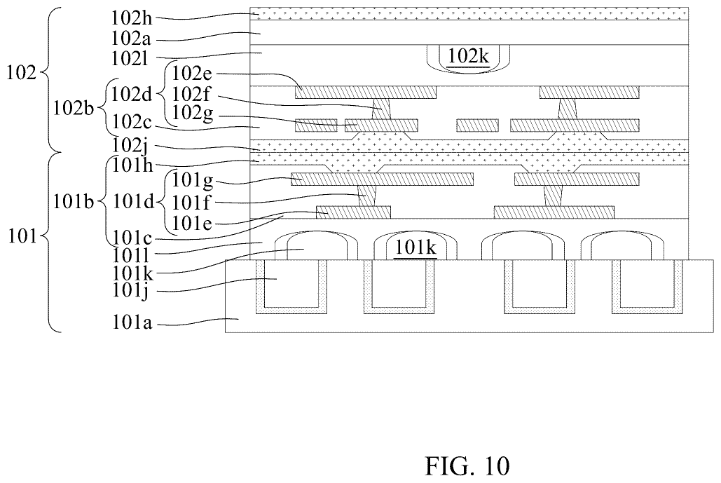

In some embodiments, referring to FIG. 10, a portion of the second substrate 102a is removed after the second die 102 is bonded to the first die 101. A grinding process may be applied to remove the portion of the second substrate 102a, after removing, the second substrate 102a may not be completely removed, and the second passivation layer 102l may not be exposed.

In some embodiments, the fourth bonding layer 102h is disposed over a remaining portion of the second substrate 102a. In some embodiments, the fourth bonding layer 102h includes dielectric material. In some embodiments, a top surface of the second substrate 102a is entirely covered by and in contact with the fourth bonding layer 102h. In some embodiments, the fourth bonding layer 102h is disposed by deposition, CVD or another suitable process.

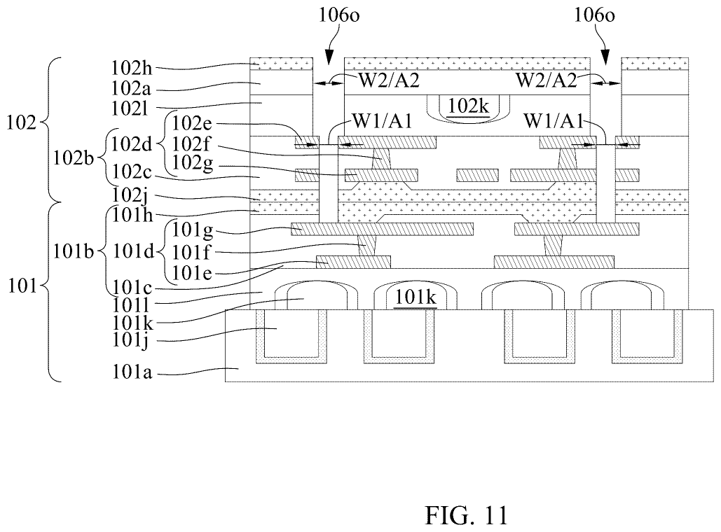

Referring to FIG. 11, a portion of the second die 102 and a portion of the first die 101 is removed to form a first opening 106o, wherein the first conductive pad 101g is exposed through the first opening 106o, and the first opening 106o includes a first part having a first width W1 surrounded by the first die 101 and a second part having a second width W2 different from the first width W1 according to step S310 in FIG. 6. In some embodiments, the first opening 106o extends through the second die 102, and a portion of the first bonding layer 101h is removed to form the first opening 106o according to step S310.

In some embodiments, the portion of the second die 102 and the portion of the first bonding layer 101h are removed by etching or any other suitable process. In some embodiments, the first opening 106o has a circular, quadrilateral or polygonal shape. In some embodiments, the formation of the fourth bonding layer 102j is performed prior to the formation of the first opening 106o, and the first opening 106o extends through the fourth bonding layer 102j.

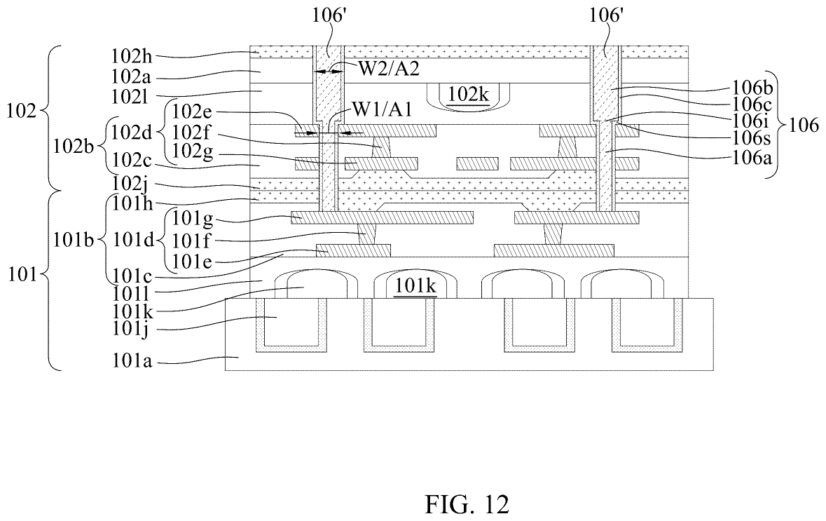

Referring to FIG. 12, a first conductive material 106′ is disposed into the first opening 106o to form a first via 106 according to step S311 in FIG. 6. In some embodiments, the first via 106 thus formed includes a first portion 106a having the first width W1 and a second portion 106b coupled to the first portion 106a and having the second width W2. In some embodiments, the second width W2 is greater than the first width W1.

In some embodiments, the a first conductive material 106′ is disposed over the first bonding layer 101h and into the first opening 106 as shown in FIG. 12. In some embodiments, the first conductive material 106′ includes gold, silver, copper, nickel, tungsten, aluminum, tin, alloys thereof, or the like. In some embodiments, the first conductive material 106′ is disposed by CVD, physical vapor deposition (PVD), sputtering or another suitable process.

After the disposing of the first conductive material 106′ as shown in FIG. 12, a portion of the first conductive material 106′ on the second bonding layer 102h is removed to form the first via 106. In some embodiments, the portion of the first conductive material 106′ is removed by planarization, etching, chemical mechanical planarization (CMP) or another suitable process. In some embodiments, the first via 106 extends through the second die 102 and the first bonding layer 101h and is in contact with the first conductive pad 101g. In some embodiments, the first via 106 protrudes from the first conductive pad 101g. In some embodiments, the first die 106 has a tapered-cross-sectional profile is formed as shown in FIG. 12.

In some embodiments, a first barrier layer 106c is formed in the first opening 106o to surround the first material 106′. In some embodiments, the first barrier layer 106c is formed prior to the formation of the first portion 106a and the second portion 106b of the first via 106.

In some embodiments, the method S300 further includes forming a third die 103.

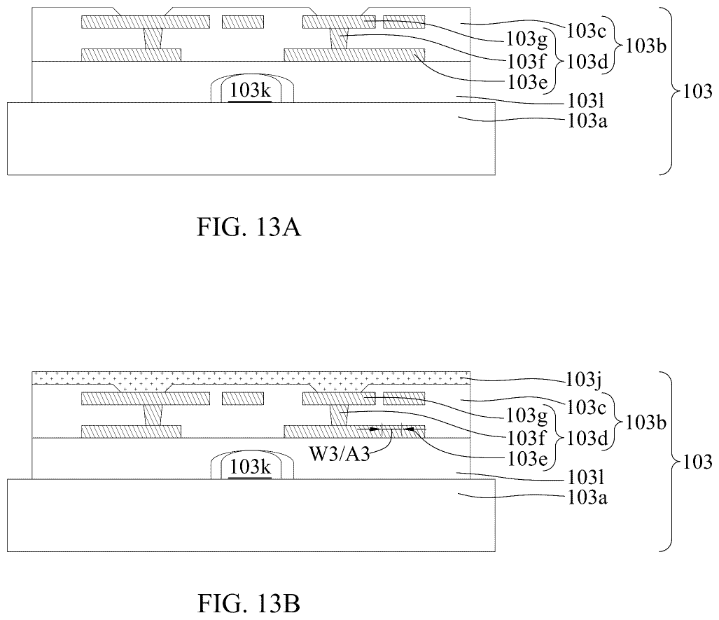

Referring to FIG. 13A, the formation of the third die 103 includes providing a third substrate 103a and a third dielectric layer 103c over the third substrate 103a. In some embodiments, the third substrate 103a is a semiconductive layer. In some embodiments, the third substrate 103a includes semiconductive material.

In some embodiments, the third dielectric layer 103c is disposed above the third substrate 103a. In some embodiments, the third dielectric layer 103c includes dielectric material. In some embodiments, the third dielectric layer 103c is formed by deposition, CVD or another suitable process. In some embodiments, a third passivation layer 103l is formed between the third substrate 103a and the third dielectric layer 103c, and a third electrical device 103k is formed over the third substrate 103a and within the third passivation layer 103l.

In some embodiments, a third interconnect structure 103d is formed within the third dielectric layer 103c. In some embodiments, the third interconnect structure 103d includes a third pad portion 103e and a third via portion 103f. In some embodiments, the third pad portion 103e and the third via portion 103f include conductive material. In some embodiments, the third pad portion 103e and the third via portion 103f are formed by removing several portions of the third dielectric layer 103c to form several recesses and disposing conductive materials to fill the recesses to form the third pad portion 103e and the third via portion 103f. In some embodiments, the conductive material is disposed by electroplating, sputtering or another suitable process.

In some embodiments, a third interconnect structure 103d within the third dielectric layer 103c and having a third conductive pad 103g. In some embodiments, the third conductive pad 103g is at least partially exposed through the third dielectric layer 103c. In some embodiments, the third conductive pad 103g is formed by removing a portion of the third dielectric layer 103c to form a recess, and then disposing conductive material to fill the recess to form the third conductive pad 103g. In some embodiments, the conductive material is disposed by electroplating, sputtering or another suitable process.

Referring to FIG. 13B, a third bonding layer 103j is disposed over the third dielectric layer 103c and in contact with the third conductive pad 103g. In some embodiments, the third bonding layer 103j includes dielectric material. In some embodiments, a top surface of the third conductive pad 103g is covered by and in contact with the third bonding layer 103j and the third dielectric layer 103c. In some embodiments, the third bonding layer 103j is disposed by deposition, CVD or another suitable process.

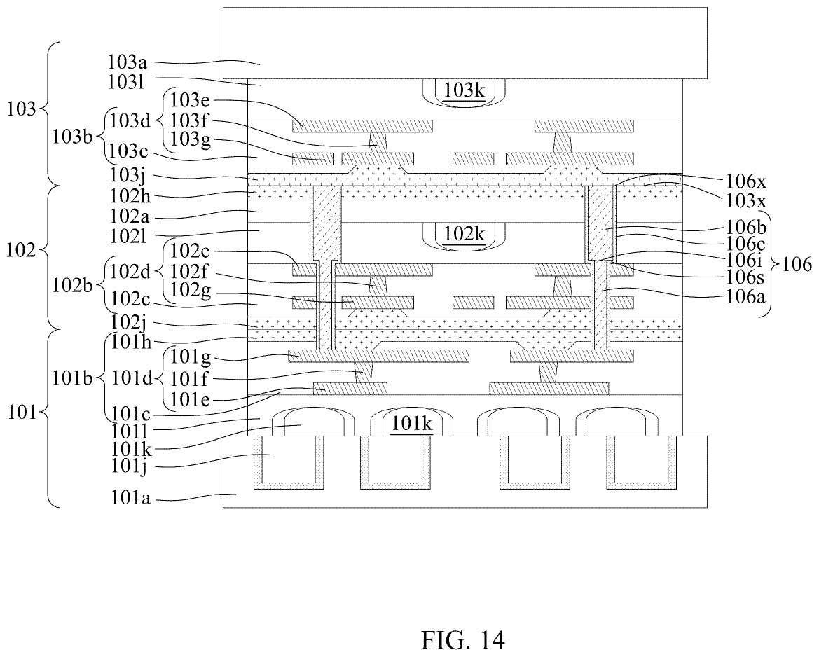

Referring to FIG. 14, in some embodiments, the third bonding layer 103j is bonded to the fourth bonding layer 102h to bond the third die 103 to the second die 102. In some embodiments, the third die 103 is bonded to the second die 102.

In some embodiments, the third die 103 and the second die 102 are respectively formed. In some embodiments, the formation of the second die 102 and the formation of the third die 103 are performed simultaneously or separately. In some embodiments, the third die 103 is flipped after the formation of the third die 103 and prior to the bonding of the third die 103 to the second die 102.

In some embodiments, a fusion bonding is performed to bond the third die 103 to the second die 102. In some embodiments, the fusion bonding includes bonding the third bonding layer 103j to the fourth bonding layer 102h.

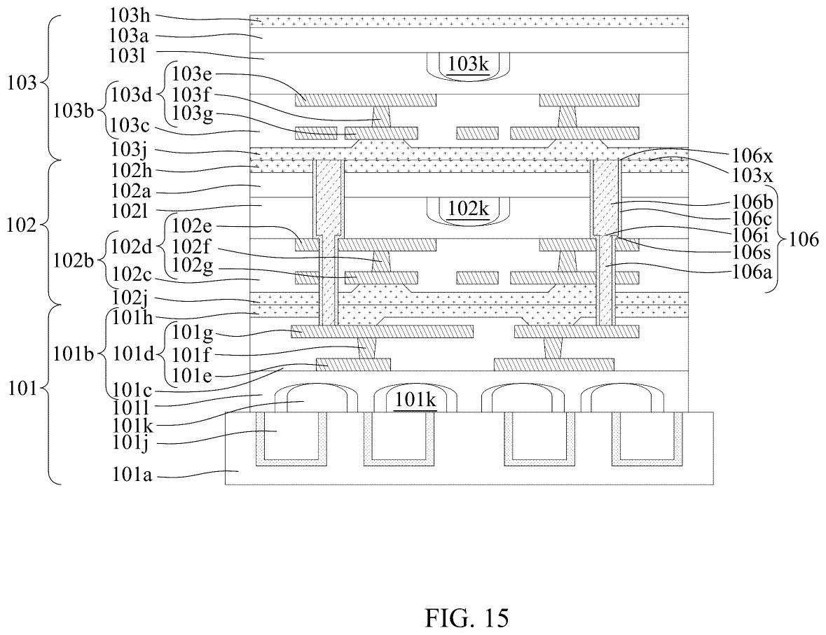

In some embodiments, referring to FIG. 15, a portion of the third substrate 103a is removed after the third die 103 is bonded to the second die 102. A grinding process may be applied to remove the portion of the third substrate 103a, after removing, the third substrate 103a may not be completely removed, and the third passivation layer 103l may not be exposed.

In some embodiments, a fifth bonding layer 103h is disposed over a remaining portion of the third substrate 103a. In some embodiments, the fifth bonding layer 103h includes dielectric material. In some embodiments, a top surface of the third substrate 103a is entirely covered by and in contact with the fifth bonding layer 103h. In some embodiments, the fifth bonding layer 103h is disposed by deposition, CVD or another suitable process.

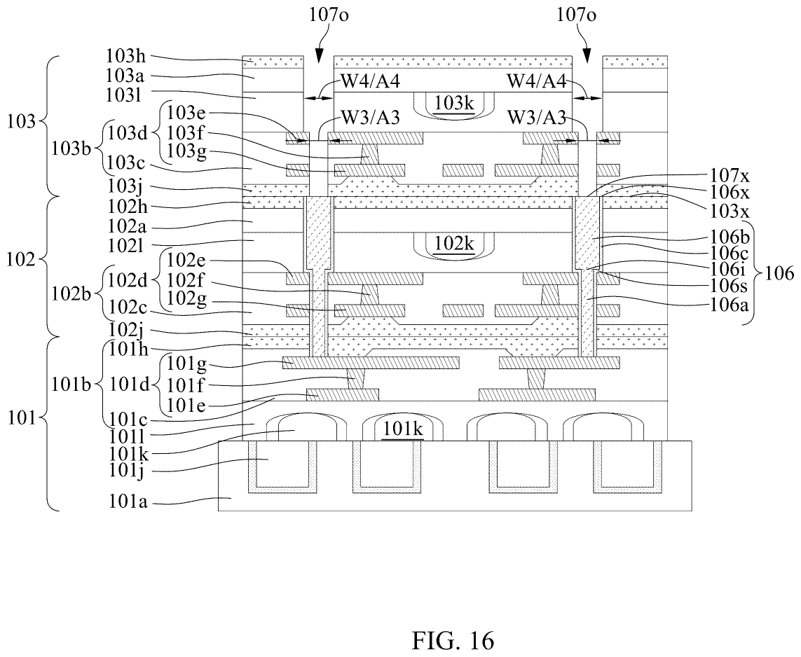

Referring to FIG. 16, a portion of the third die 103 is removed to form a second opening 107o, wherein the first via 106 is exposed through the second opening 107o, and the second opening 107o includes a third part having a third width W3 and a fourth part having a fourth width W4 different from the third width W3. In some embodiments, the third width W3 is different from the second width W2. In some embodiments, the second opening 107o extends through the third die 103.

In some embodiments, the portion of the third die 103 is removed by etching or any other suitable process. In some embodiments, the second opening 107o has a circular, quadrilateral or polygonal shape.

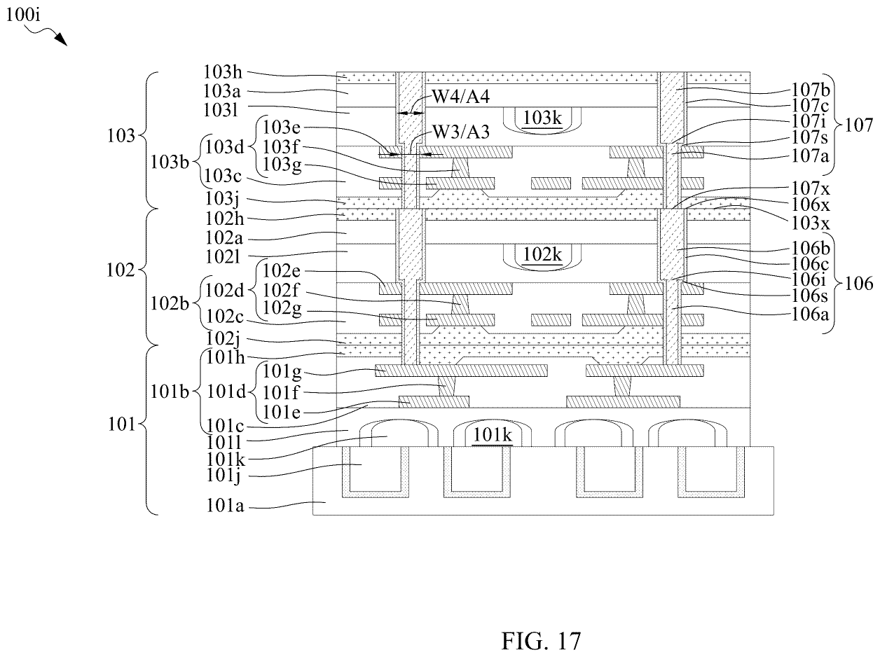

Referring to FIG. 17, a second conductive material 107′is disposed into the second opening 107o to form a second via 107. In some embodiments, the second via 107 thus formed possesses a tapered cross-sectional profile. In some embodiments, the second via 107 thus formed includes a third portion 107a having the third width W3 and a fourth portion 107b coupled to the third portion 107a and having the fourth width W4. In some embodiments, the fourth width W4 is greater than the third width W3. In some embodiments, the third portion 107a is coupled to the second portion of the first via 106.

In some embodiments, the second conductive material 107′is disposed over the first via 106 and into the second opening 107 as shown in FIG. 17. In some embodiments, the second conductive material 107′includes gold, silver, copper, nickel, tungsten, aluminum, tin, alloys thereof, or the like. In some embodiments, the second conductive material 107′is disposed by CVD, PVD, sputtering or another suitable process.

After the disposing of the second conductive material 107′, a portion of the second conductive material 107′on the fifth bonding layer 103h is removed to form the second via 107. In some embodiments, the portion of the second conductive material 107′is removed by planarization, etching, CMP or another suitable process. In some embodiments, the second via 107 extends through the third die 103 is in contact with the first via 106. In some embodiments, a step-shaped structure is formed at a junction of the first die 106 and the second via 107.

In some embodiments, a second barrier layer 107c is formed in the second opening 107o to surround the second conductive material 107′. In some embodiments, the second barrier layer 107c is formed prior to the formation of the third portion 107a and the fourth portion 107b the second via 107. In some embodiments, an intermediate structure 100i as shown in FIG. 17 is formed.

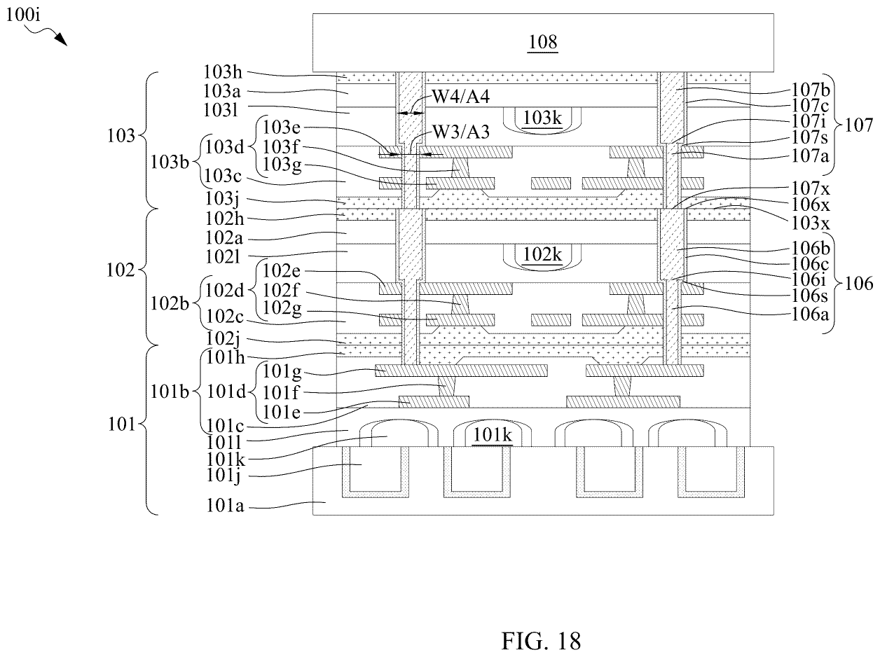

Referring to FIG. 18, a carrier substrate 108 is disposed over the fifth bonding layer 103h. In some embodiments, the intermediate structure 100i is attached to the carrier substrate 108 by the fifth bonding layer 103h. In some embodiments, the carrier substrate 108 is a blank or dummy substrate for supporting the intermediate structure 100i to undergo further processing. In some embodiments, the intermediate structure 100i is detachable from the carrier substrate 108. In some embodiments, the fifth bonding layer 103h faces toward the carrier substrate 108.

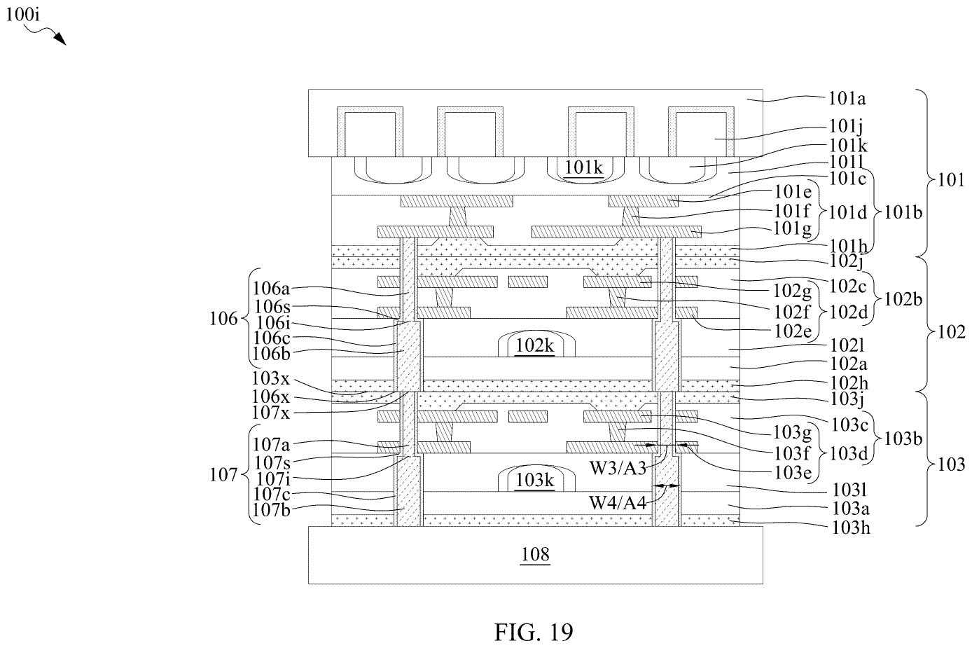

Referring to FIG. 19, in some embodiments, the intermediate structure 100i as shown in FIG. 18 is flipped and attached to the carrier substrate 108.

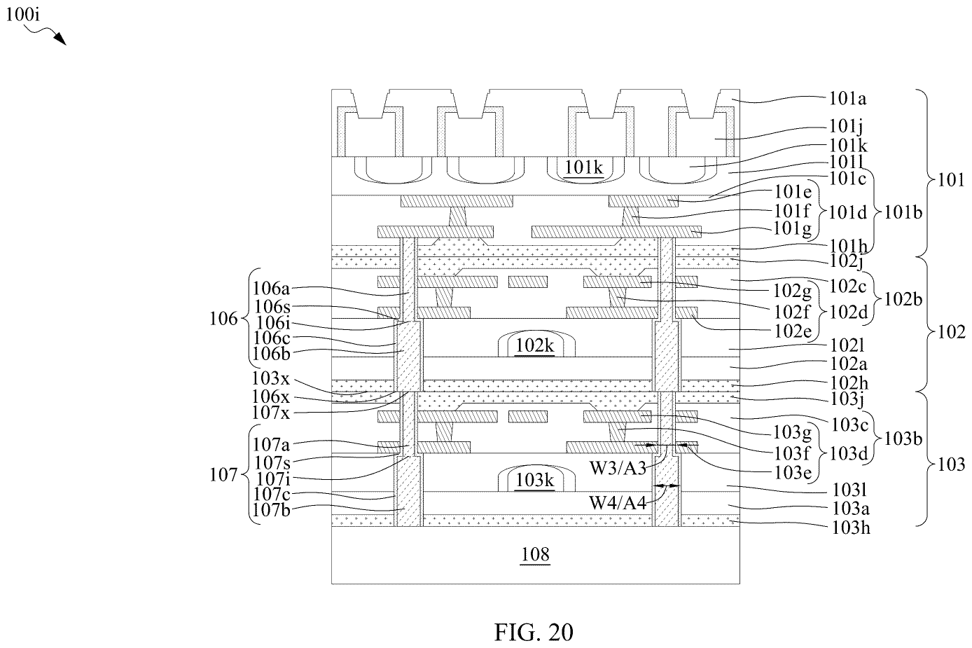

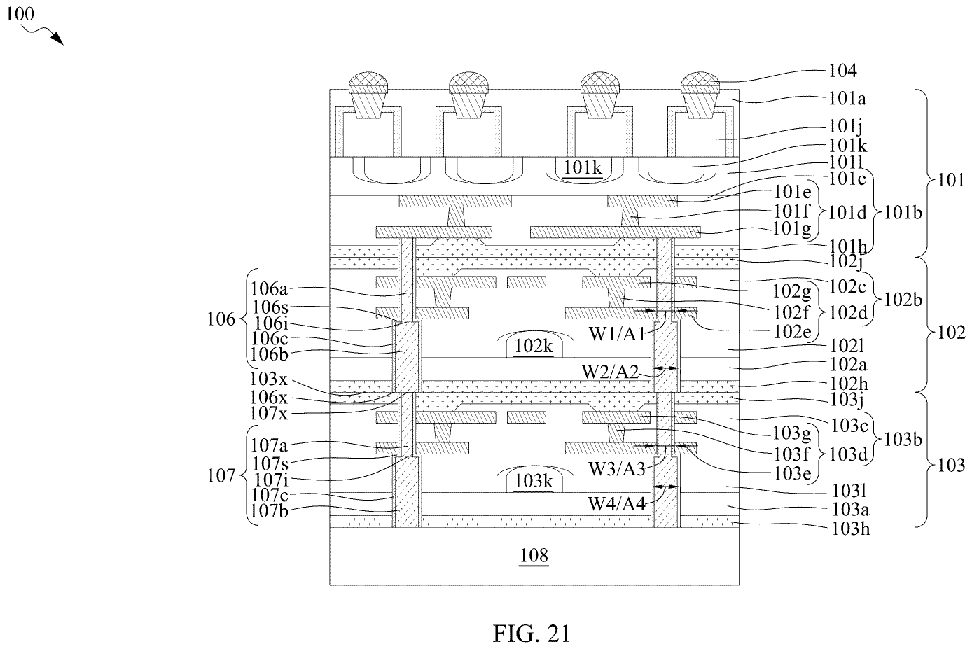

In some embodiments, a conductive bump 104 is formed as shown in FIGS. 20 to 21. In some embodiments, a portion of a first substrate 101a is removed to expose a portion of a third via 101j as shown in FIG. 20, and then the conductive bump 104 is formed over the third via 101j as shown in FIG. 21. In some embodiments, the conductive bump 104 is electrically connected to the third die 103.

In some embodiments, the conductive bump 104 includes low-temperature reflowable material. In some embodiments, the conductive bump 104 includes soldering material such as tin, lead, silver, copper, nickel, bismuth, or a combination thereof. In some embodiments, the conductive bump 104 includes conductive material such as gold, silver, copper, nickel, tungsten, aluminum, tin, alloys thereof, or the like. In some embodiments, the conductive bump 104 is a ball grid array (BGA) ball, a controlled collapse chip connection (C4) bump, a microbump or the like. In some embodiments, a first semiconductor structure 100 as shown in FIG. 1 is formed.

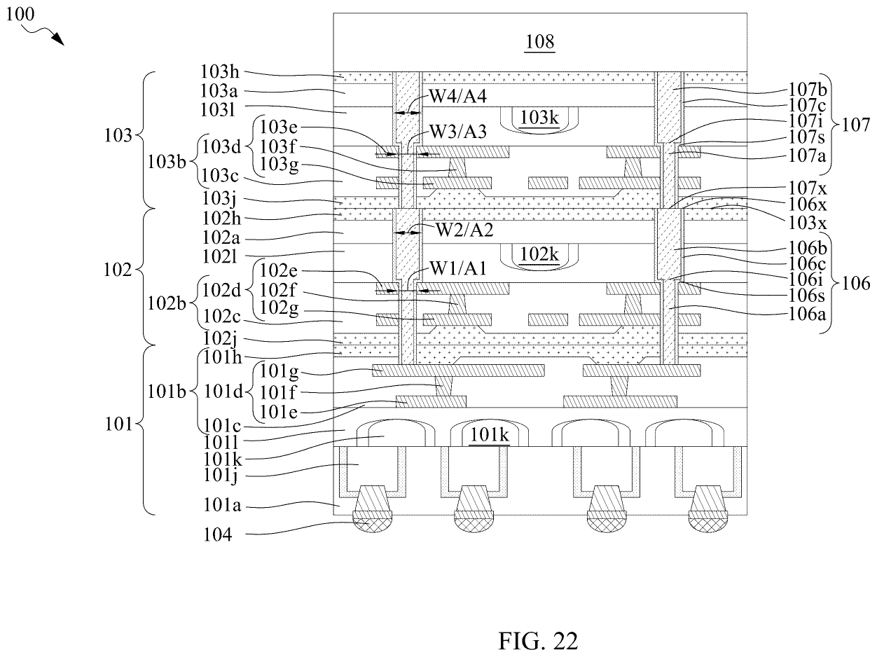

Referring to FIG. 22, in some embodiments, the first semiconductor structure 100 as shown in FIG. 21 is flipped.

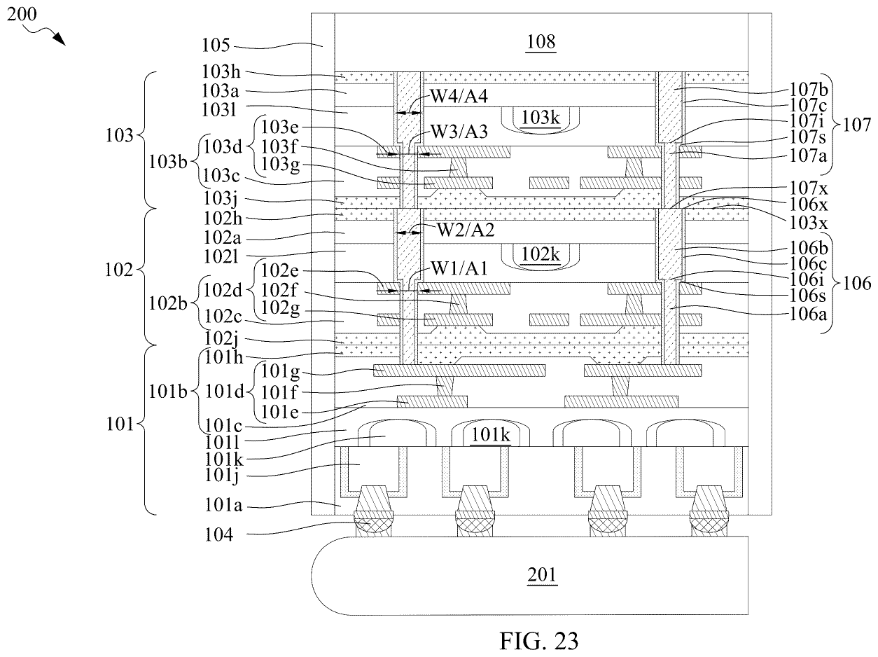

Referring to FIG. 23, a molding 105 is formed to surround the first die 101, the second die 102 and the third die 103. In some embodiments, the first semiconductor structure 100 as shown in FIG. 22 is attached to an interposer 201, and a second semiconductor structure 200 as shown in FIG. 5 is formed.

In conclusion, a first die is bonded to a second die by fusion bonding, and a through silicon via (TSV) in the second die and extended into the first die and electrically coupled to a conductive pad of the first dia. A dielectric-to-dielectric bonding interface is formed between the first die and the second die, the TSV possesses a tapered cross-sectional profile, and therefore a thickness of the semiconductor structure may be decrease to increase density of the semiconductor structure (z-height of the product). As a result, that the costs are reduced, and favorable electrical performance and reliability of the high-density semiconductor structure are guaranteed.

One aspect of the present disclosure provides a semiconductor structure. The semiconductor structure includes a first die, a second die and a first via. The first die includes a first substrate, a first dielectric layer over the first substrate, a first interconnect structure disposed within the first dielectric layer and having a first conductive pad, and a first bonding layer over the first dielectric layer, wherein the first conductive pad is at least partially exposed through the first dielectric layer. The second die includes a second bonding layer bonded to the first bonding layer, a second substrate over the second bonding layer, and a second interconnect structure between the second bonding layer and the second substrate. The first via extends through the second die and the first bonding layer and coupled to the first conductive pad.

The first via includes a first portion having a first width and a second portion coupled to the first portion and having a second width different from the first width, wherein the first portion is surrounded by the first bonding layer and adjacent to the second interconnect structure, and the second portion is surrounded by the second substrate.

Another aspect of the present disclosure provides a semiconductor structure. The semiconductor structure includes a first die, a second die, a third die, a first via and a second via. The first die includes a first substrate, a first interconnect structure disposed over the first substrate and having a first conductive pad, and a first bonding layer over the first conductive pad. The second die includes a second bonding layer bonded to the first bonding layer, a second substrate over the second bonding layer, and a second interconnect structure between the second bonding layer and the second substrate. The third die includes a third bonding layer bonded to the second die, a third substrate over the third bonding layer, and a third interconnect structure between the third bonding layer and the third substrate. The first via extends through the second die and into the first die. The second via extends through the third die and electrically connected to the first via. The second die is disposed between the first die and the third die, the first via possesses a tapered cross-sectional profile, a first contact surface area of the first via is in contact with a second contact surface area of the second via, and a dimension of the first contact surface area is different from a dimension of the second contact surface area.

Another aspect of the present disclosure provides a method of manufacturing a semiconductor structure. The method includes steps of forming a first die, forming a second die, and bonding the second die over the first die. The formation of the first die includes providing a first substrate and a first dielectric layer over the first substrate, forming a first interconnect structure within the first dielectric layer and having a first conductive pad, disposing a first bonding layer over the first dielectric layer and in contact with the first conductive pad.

The formation of the second die includes providing a second substrate and a second dielectric layer over the second substrate, forming a second interconnect structure within the second dielectric layer and having a second conductive pad, disposing a second bonding layer over the second dielectric layer and in contact with the second conductive pad.

The method further includes bonding the first bonding layer to the second bonding layer to bond the first die to the second die; removing a portion of the second die and a portion of the first bonding layer to form a first opening, wherein the first conductive pad is exposed through the first opening, and the first opening includes a first part having a first width surrounded by the first die and a second part having a second width different from the first width; and disposing a first conductive material into the first opening to form a first via. The first via includes a first portion having the first width and a second portion coupled to the first portion and having the second width.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor structure, comprising:
a first die including a first substrate, a first interconnect structure disposed over the first substrate and having a first conductive pad, and a first bonding layer over the first conductive pad;
a second die including a second bonding layer bonded to the first bonding layer, a second substrate over the second bonding layer, and a second interconnect structure between the second bonding layer and the second substrate; a third die including a third bonding layer bonded to the second die, a third substrate over the third bonding layer, and a third interconnect structure between the third bonding layer and the third substrate;
a first via extending through the second die and into the first die; and
a second via extending through the third die and electrically connected to the first via,
wherein the second die is disposed between the first die and the third die, the first via possesses a tapered cross-sectional profile, a first contact surface area of the first via is in contact with a second contact surface area of the second via, and a dimension of the first contact surface area is different from a dimension of the second contact surface area.

2. The semiconductor structure of claim 1, wherein the dimension of the first contact surface area is substantially greater than the dimension of the second contact surface area.

3. The semiconductor structure of claim 1, wherein a portion of the first contact surface area of the first via is in contact with the third bonding layer.

4. The semiconductor structure of claim 1, wherein the first via includes a first portion having a first width and a second portion coupled to the first portion and having a second width different from the first width, wherein the second portion is disposed between the first portion and the second via.

5. The semiconductor structure of claim 1, further comprising a molding surrounding the first die and the second die.

6. A method of manufacturing a semiconductor structure, comprising:
forming a first die including:
providing a first substrate and a first dielectric layer over the first substrate;
forming a first interconnect structure within the first dielectric layer and having a first conductive pad;
disposing a first bonding layer over the first dielectric layer and in contact with the first conductive pad;
forming a second die including:
providing a second substrate and a second dielectric layer over the second substrate;
forming a second interconnect structure within the second dielectric layer and having a second conductive pad;
disposing a second bonding layer over the second dielectric layer and in contact with the second conductive pad;
bonding the first bonding layer to the second bonding layer to bond the first die to the second die;
removing a portion of the second die and a portion of the first bonding layer to form a first opening, wherein the first conductive pad is exposed through the first opening, and the first opening includes a first part having a first width surrounded by the first die and a second part having a second width different from the first width; and
disposing a first conductive material into the first opening to form a first via,
wherein the first via includes a first portion having the first width and a second portion coupled to the first portion and having the second width.

7. The method of claim 6, wherein the second die is flipped after the formation of the second die and prior to the bonding of the second die to the first die.

8. The method of claim 6, wherein the bonding of the second die to the first die is performed by a fusion bonding.

9. The method of claim 6, further comprising forming a barrier layer in the first opening to surround the first conductive material.

10. The method of claim 6, further comprising:
forming a third die including:
providing a third substrate and a third dielectric layer over the third substrate; p2 forming a third interconnect structure within the third dielectric layer and having a third conductive pad;
disposing a third bonding layer over the third dielectric layer and in contact with the third conductive pad;
disposing a fourth bonding layer over the second substrate;
bonding the third bonding layer to the fourth bonding layer to bond the third die to the second die;
removing a portion of the third die to form a second opening, wherein the first via is exposed through the second opening, and the second opening includes a third part having a third width surrounded by the third dielectric layer and a fourth part having a fourth width different from the third width and surrounded by the third substrate; and
disposing a second conductive material into the second opening to form a second via,
wherein the second via includes a third portion having the third width and a fourth portion having the fourth width.

11. The method of claim 10, wherein the formation of the fourth bonding layer is performed prior to the formation of the first opening.

12. The method of claim 10, wherein the third width is different from the second width.

13. The method of claim 6, wherein the first conductive material is disposed by chemical vapor deposition (CVD), physical vapor deposition (PVD) or sputtering.

14. The method of claim 6, wherein formation of the first via is performed prior to the formation of the second via, and the second via is coupled to the first via.

15. The method of claim 6, wherein the first opening has a circular, quadrilateral or polygonal shape.

16. The method of claim 6, wherein the formation of the first die and the formation of the second die are performed separately.

17. The method of claim 10, wherein the formation of the first die is performed prior to the formation of the third die.

18. The method of claim 10, wherein the first via and the second via include a same material.

19. The method of claim 6, further comprising forming a molding to surround the first die and the second die.
